(19) United States
(12) Patent Application Publication
(10) Pub. No.: US 2024/0414948 A1
(43) Pub. Date: Dec. 12, 2024

(54) DISPLAY DEVICE

(71) Applicant: Samsung Display Co., LTD., Yongin-si (KR)

(72) Inventors: Young Seok BAEK, Yongin-si (KR); Chong Sup CHANG, Yongin-si (KR); Sang Jin PARK, Yongin-si (KR); In Kyung YOO, Yongin-si (KR)

(21) Appl. No.: 18/592,129

(22) Filed: Feb. 29, 2024

(30) Foreign Application Priority Data
Jun. 9, 2023 (KR) 10-2023-0073923

(51) Int. Cl. H10K 59/122; H10K 59/80

(52) U.S. Cl. CPC H10K 59/122; H10K 59/80521

(57) ABSTRACT

A display device includes a substrate including an emission area and a non-emission area; a via layer disposed on the substrate and including a recess toward the substrate; a pixel-defining layer overlapping the non-emission area and disposed on the via layer; a first bank layer disposed on the pixel-defining layer and defining a first opening; a second bank layer disposed on the first bank layer and including a tip protruding toward the first opening from a side surface of the first bank layer; a first pixel electrode overlapping the recess of the via layer and disposed on the substrate; a first emissive layer disposed on the first pixel electrode in the first opening; and a first common electrode disposed on the first emissive layer in the first opening and in contact with the first bank layer.

This application claims priority to Korean Patent Application No. 10-2023-0073923, filed on Jun. 9, 2023, and all the benefits accruing therefrom under 35 U.S.C. § 119, the content of which in its entirety is herein incorporated by reference.

### BACKGROUND

### 1. Field of the Disclosure

The present disclosure relates to a display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat-panel display devices such as, for example, a liquid-crystal display device, a field emission display device, and an organic light-emitting display device. Among such flat panel display devices, a light-emitting display device may include a light-emitting element that can emit light on its own, such that each of the pixels of the display panel is capable of self-emitting light. Accordingly, a light-emitting display device can display images without a backlight unit for supplying light to the display panel.

### SUMMARY

Aspects of the present disclosure provide a display device that reduces structural defects associated with some bank structures.

Aspects of the present disclosure provide a display device that improves aperture ratio, for example, by preventing or eliminating reductions in aperture ratio due to structural defects of a bank structure.

It should be noted that objects of the present disclosure are not limited to the above-mentioned objects, and other objects of the present disclosure will be apparent to those skilled in the art from the following descriptions.

An embodiment of a display device includes a substrate including an emission area and a non-emission area; a via layer disposed on the substrate and including a recess toward the substrate; a pixel-defining layer overlapping the non-emission area and disposed on the via layer; a first bank layer disposed on the pixel-defining layer and defining a first opening; a second bank layer disposed on the first bank layer and including a tip protruding toward the first opening from a side surface of the first bank layer; a first pixel electrode overlapping the recess of the via layer and disposed on the substrate; a first emissive layer disposed on the first pixel electrode in the first opening; and a first common electrode disposed on the first emissive layer in the first opening and in contact with the first bank layer, wherein the side surface of the first bank layer and the tip of the second bank layer overlap the recess of the via layer.

A first portion of the via layer has first thickness and overlaps the recess; a second portion of the via layer has a second thickness and does not overlap the recess; and the first thickness is different from the second thickness.

The first thickness may be smaller than the second thickness.

The first opening may overlap the recess of the via layer.

A width of the first opening in a direction parallel to the substrate may be smaller than a width of the recess of the via layer.

The via layer may further comprise an inclined surface overlapping the non-emission area and not overlapping the recess.

The first pixel electrode may be in contact with the inclined surface.

The pixel-defining layer may be spaced apart from the first pixel electrode in a direction perpendicular to the substrate in the recess of the via layer.

A display device may include a pattern layer disposed in a region where the first pixel electrode and the pixel-defining layer is spaced apart from each other, wherein the pattern layer overlaps the recess of the via layer and may be in contact with the first emissive layer.

A display device may include a first organic pattern disposed on the second bank layer, wherein the first organic pattern includes a same material as the first emissive layer and is spaced apart from the first emissive layer; and a first electrode pattern disposed on the first organic pattern, wherein the first electrode pattern includes a same material as the first common electrode and is spaced apart from the first common electrode, wherein the first organic pattern and the first electrode pattern may overlap the recess of the via layer.

A display device may include a second pixel electrode spaced apart from the first pixel electrode, wherein the via layer is interposed between the second pixel electrode and the first pixel electrode; a second emissive layer disposed on the second pixel electrode; a second common electrode on the second emissive layer; and a second electrode pattern disposed on the second bank layer, wherein the second electrode pattern includes a same material as the second common electrode and is spaced apart from the second common electrode.

A display device may include a first inorganic layer covering the first common electrode and the first electrode pattern; and a second inorganic layer covering the second common electrode and the second electrode pattern, wherein the first inorganic layer and the second inorganic layer may be spaced apart from each other.

A display device may include a subsidiary via layer disposed between the substrate and the via layer, wherein a surface of the subsidiary via layer may overlap the recess of the via layer and is exposed by the recess, and wherein the exposed surface of the subsidiary via layer may be in contact with the first pixel electrode.

The via layer may comprise a first surface facing the subsidiary via layer; a second surface opposed to the first surface; and an inclined surface connecting the first surface with the second surface.

A width of the first surface may be greater than a width of the second surface, and wherein an angle formed by the first surface and the inclined surface may be an acute angle.

The via layer and the subsidiary via layer may include a same material.

The via layer and the subsidiary via layer may include different materials.

An embodiment of a display device includes a substrate comprising an emission area and a non-emission area; a via layer disposed on the substrate and comprising a recess toward the substrate; a pixel-defining layer overlapping the non-emission area, disposed on the via layer and defining a first opening; a first bank layer overlapping the non-emission area and disposed on the pixel-defining layer; a second bank layer disposed on the first bank layer and comprising a tip protruding toward the first opening from a side surface of the first bank layer; a first pixel electrode disposed on the via layer in the recess of the via layer; a first emissive layer disposed on the first pixel electrode in the first opening; and a first common electrode disposed on the first emissive layer in the first opening and in contact with the first bank layer, wherein the first opening may overlap the recess of the via layer.

A width of the first opening may be smaller than a width of the recess of the via layer.

A side surface of the pixel-defining layer facing the first opening may be located in the recess of the via layer, and the side surface of the pixel-defining layer overlaps the via layer in a direction parallel to the substrate.

According to the embodiments of the present disclosure, a display device is described having improved electrical contact between a common electrode and a bank structure, in which electrical contact failure between the common electrode and the bank structure is mitigated or reduced.

According to the embodiments of the present disclosure, a display device is described having improved lifetime and efficiency.

It should be noted that effects of the present disclosure are not limited to those described herein and other effects of the present disclosure will be apparent to those skilled in the art from the following descriptions.

### BRIEF DESCRIPTION OF THE DRAWINGS

These and/or other features of embodiments of the invention will become apparent and more readily appreciated from the following description of the embodiments, taken in conjunction with the accompanying drawings, in which:

FIG. 1 is a perspective view of an electronic device according to an embodiment of the present disclosure.

FIG. 2 is a perspective view showing a display device included in an electronic device according to an embodiment of the present disclosure.

FIG. 3 is a cross-sectional view of the display device of FIG. 2 viewed from the side.

FIG. 4 is a plan view showing a display layer of a display device according to an embodiment of the present disclosure.

FIG. 5 is a plan view showing an arrangement of emission areas in a first display area of a display device according to an embodiment.

FIG. 6 is a cross-sectional view taken along line X1-X1′ of FIG. 5.

FIG. 7 is an enlarged cross-sectional view of area A of FIG. 6.

FIG. 8 is an enlarged, cross-sectional view of area T of FIG. 7.

FIG. 9 is a cross-sectional view of another example, taken along line X1-X1′ of FIG. 5.

FIG. 10 is an enlarged cross-sectional view of area P of FIG. 9.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided such that the disclosure will be thorough and complete, and will fully convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” “third,” or the like may be used herein to describe various elements, these elements are not to be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described with reference to the accompanying drawings.

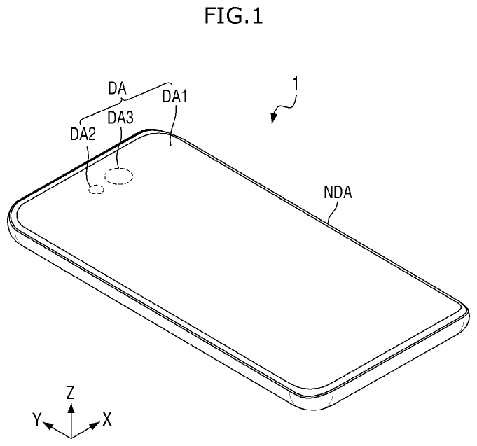

FIG. 1 is a plan view of an electronic device 1 according to an embodiment of the present disclosure.

Referring to FIG. 1, an electronic device 1 displays a moving image or a still image. The electronic device 1 may refer to any electronic device that provides a display screen. For example, the electronic device 1 may include a television set, a laptop computer, a monitor, an electronic billboard, Internet-of-Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console, a digital camera, a camcorder, or the like.

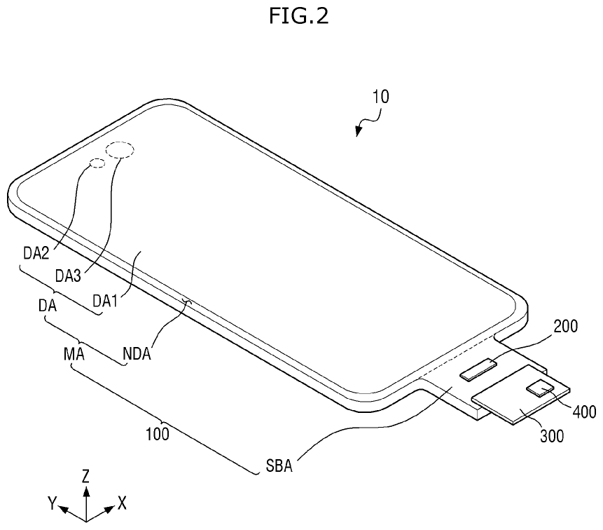

The electronic device 1 may include a display device 10 (see FIG. 2) for providing a display screen. Examples of the display device 10 may include an inorganic light-emitting diode display device, an organic light-emitting display device, a quantum-dot light-emitting display device, a plasma display device, a field emission display device, and the like. In the descriptions herein, an organic light-emitting diode display device is employed as an example of the display device 10, but the present disclosure is not limited thereto. Any other suitable display device may be employed in association the application of the technical ideas of the present disclosure.

The shape of the electronic device 1 may be modified in a variety of ways. For example, the electronic device 1 may have shapes such as, for example, a rectangle with longer lateral sides, a rectangle with longer vertical sides, a square, a quadrangle with rounded corners (vertices), other polygons, a circle, and the like. The shape of a display area DA of the electronic device 1 may also be similar to the overall shape of the electronic device 1. In the example shown in FIG. 1, the electronic device 1 has a rectangular shape with the longer sides in the second direction (y-axis direction).

The electronic device 1 may include the display area DA and a non-display area NDA. In the display area DPA, images can be displayed. In the non-display area NDA, images are not displayed. The display area DPA may be referred to as an active area, while the non-display area NDA may also be referred to as an inactive area. The display area DA may generally occupy the center of the electronic device 1.

The display area DA may include a first display area DA1, a second display area DA2 and a third display area DA3. In the second display area DA2 and the third display area DA3, components for providing a variety of features of the electronic device 1 may be disposed. In other words, the second display area DA2 and the third display area DA3 may be referred to as component areas.

FIG. 2 is a perspective view showing a display device 10 included in an electronic device 1 according to an embodiment of the present disclosure.

Referring to FIG. 2, the electronic device 1 according to an embodiment of the present disclosure may include a display device 10. The display device 10 may provide a display screen where images are displayed in the electronic device 1. The display device 10 may have a shape similar to the shape of the electronic device 1 when viewed from the top. For example, the display device 10 may have a rectangular shape having shorter sides in the first direction (x-axis direction) and longer sides in the second direction (y-axis direction), similar to the rectangular shape of the electronic device 1. The corners where the shorter sides in the first direction (x-axis direction) meet the longer sides in the second direction (y-axis direction) may be rounded with a predetermined curvature. It should be understood, however, that the present disclosure is not limited thereto. The corners may be formed at a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300, and a touch driver 400.

The display panel 100 may include a main area MA and a subsidiary area SBA (also referred to herein as an auxiliary area or secondary area).

The main area MA may include the display area DA including pixels for displaying images, and the non-display area NDA located around the display area DA. The display area DA may include the first display area DA1, the second display area DA2, and the third display area DA3. The display area DA may output light from a plurality of emission areas or a plurality of open areas. For example, the display panel 100 may include a pixel circuit including switching elements, a pixel-defining layer that defines the emission areas or the opening areas, and a self-light-emitting element.

In an example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be disposed on the outer side of the display area DA. The non-display area NDA may be defined as the edge area of the main area MA of the display panel 100. The non-display area NDA may include a gate driver (not shown) that applies gate signals to gate lines, and the non-display area NDA may include fan-out lines (not shown) that connect the display driver 200 with the display area DA.

The subsidiary area SBA may extend from one side of the main area MA. The subsidiary area SUB may include a flexible material that can be bent, folded, or rolled. For example, when the subsidiary area SBA is bent, the subsidiary area SBA may overlap the main area MA in the thickness direction (third direction or z-axis direction). The subsidiary area SBA may include pads connected to the display driver 200 and the circuit board 300. According to another embodiment, the subsidiary area SBA may be omitted, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached to the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction as the subsidiary area SBA is bent. In another example, the display driver 200 may be mounted on the circuit board 300.

The circuit board 300 may be attached on the pad area of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as, for example, a chip-on-film (COF).

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signal may be a pulse signal of a predetermined frequency. The touch driver 400 may determine whether there is an input and may find the coordinates of the input based on the amount of the change in the capacitance between the touch electrodes. The touch driver 400 may be implemented as an integrated circuit (IC).

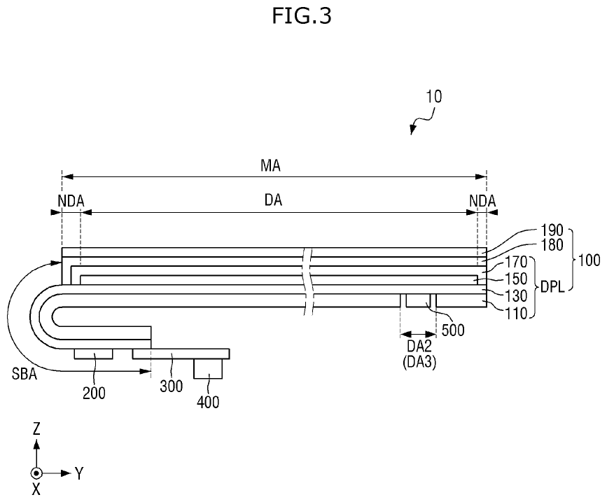

FIG. 3 is a cross-sectional view of the display device 10 of FIG. 2 viewed from a side of the display device 10.

Referring to FIG. 3, the display panel 100 may include a display layer DPL, a touch sensing layer 180, and a color filter layer 190. The display layer DPL may include a substrate 110, a thin-film transistor layer 130, an emission material layer 150, a thin-film encapsulation layer 170.

The substrate 110 may be a base substrate or a base member. The substrate 110 may be a flexible substrate that can be bent, folded, or rolled. For example, the substrate 110 may include, but is not limited to, a polymer resin such as, for example, polyimide PI. In another example, the substrate 110 may include a glass material or a metal material.

The thin-film transistor layer 130 may be disposed on the substrate 110. The thin-film transistor layer 130 may include a plurality of thin-film transistors forming pixel circuits of pixels. The thin-film transistor layer 130 may include gate lines, data lines, voltage lines, gate control lines, fan-out lines for connecting the display driver 200 with the data lines, lead lines for connecting the display driver 200 with the pads, and other components supportive of functions of display device 10. Each of the thin-film transistors may include a semiconductor region, a source electrode, a drain electrode, and a gate electrode. For example, when the gate driver is formed on one side of the non-display area NDA of the display panel 100, the gate driver may include thin-film transistors.

The thin-film transistor layer 130 may be disposed in the display area DA, the non-display area NDA, and the subsidiary area SBA. The thin-film transistors in each of the pixels in the thin-film transistor layer TFTL, the gate lines, the data lines, and the voltage lines may be disposed in the display area DA. The gate control lines and the fan-out lines in the thin-film transistor layer TFTL may be disposed in the non-display area NDA. The lead lines of the thin-film transistor layer 130 may be disposed in the subsidiary area SBA.

The emission material layer 150 may be disposed on the thin-film transistor layer 130. The emission material layer 150 may include a plurality of light-emitting elements each including a first electrode, a second electrode and an emissive layer to emit light, and a pixel-defining layer for defining the pixels. The plurality of light-emitting elements in the emission material layer 150 may be disposed in the display area DA.

According to an embodiment of the present disclosure, the emissive layer may be an organic emissive layer including an organic material. The emissive layer may include a hole transporting layer, an organic light-emitting layer, and an electron transporting layer. When the first electrode receives a voltage and the second electrode receives a cathode voltage through the thin-film transistors of the thin-film transistor layer 130, the holes and electrons may move to the organic light-emitting layer through the hole transporting layer and the electron transporting layer, respectively, such that the holes and electrons combine in the organic light-emitting layer to emit light.

According to another embodiment, the light-emitting elements may include quantum-dot light-emitting diodes each including a quantum-dot emissive layer, inorganic light-emitting diodes each including an inorganic semiconductor, or micro light-emitting diodes.

The thin-film encapsulation layer 170 may cover the upper and side surfaces of the emission material layer 150, and can protect the emission material layer 150. The thin-film encapsulation layer 170 may include at least one inorganic film and at least one organic film for encapsulating the emission material layer 150.

The touch sensing layer 180 may be disposed on the thin-film encapsulation layer 170. The touch sensing layer 180 may include a plurality of touch electrodes for sensing a user's touch by capacitive sensing, and the touch sensing layer 180 may include touch lines connecting the plurality of touch electrodes with the touch driver 400. For example, the touch sensing layer 180 may sense a user's touch by mutual capacitance sensing or self-capacitance sensing.

In another example, the touch sensing layer 180 may be disposed on a separate substrate disposed on the display layer DPL. In this instance, the substrate supporting the touch sensing layer 180 may be a base member encapsulating the display layer DPL.

The plurality of touch electrodes of the touch sensing layer 180 may be disposed in a touch sensor area overlapping the display area DA. The touch lines of the touch sensing layer 180 may be disposed in a touch peripheral area overlapping the non-display area NDA.

In some embodiments, the display device 10 may further include an optical device 500. The optical device 500 may be disposed in the second display area DA2 or the third display area DA3. The optical device 500 may output or receive light of infrared, ultraviolet, and visible ranges. For example, the optical device 500 may be an optical sensor that senses light incident on the display device 10, such as, for example, a proximity sensor, an illuminance sensor, a camera sensor and an image sensor.

The color filter layer 190 may be disposed on the thin-film encapsulation layer 170 in line with the emission areas. The color filter layer 190 may include a plurality of color filters associated with the plurality of emission areas, respectively. Each of the color filters may selectively transmit light of a particular wavelength and block or absorb light of other wavelengths. The color filter layer 190 may absorb some of light introduced from the outside of the display device 10 to reduce the reflection of external light. Accordingly, the color filter layer 190 can prevent distortion of colors due to the reflection of external light.

In some embodiments, the color filter layer 190 is disposed directly on the thin-film encapsulation layer 170, and the display device 10 may be implemented without a separate substrate for the color filter layer 190. Therefore, the thickness of the display device 10 can be relatively small.

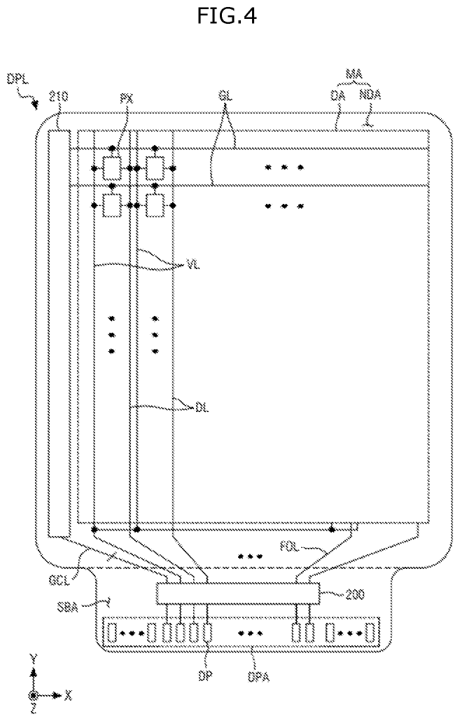

FIG. 4 is a plan view showing the display layer DPL of the display device 10 according to one or more embodiments. Referring to FIG. 4, the display layer DPL may include the main area MA and the subsidiary area SBA, and the main area MA may include the display area DA and the non-display area NDA.

The display area DA may be disposed at the center of display device 10. In the display area DA, a plurality of pixels PX, a plurality of gate lines GL, a plurality of data lines DL, and a plurality of voltage lines may be disposed. Each of the plurality of pixels PX may be defined as the minimum unit that outputs light.

The plurality of gate lines GL may supply the gate signals received from the gate driver 210 to the plurality of pixels PX. The plurality of gate lines GL may extend in the first direction (x-axis direction) and may be spaced apart from each other in the second direction (y-axis direction) crossing the first direction (x-axis direction).

The plurality of data lines DL may supply the data voltages received from the display driver 200 to the plurality of pixels PX. The plurality of data lines DL may extend in the second direction (y-axis direction) and may be spaced apart from each other in the first direction (x-axis direction).

The plurality of voltage lines VL may apply the supply voltage received from the display driver 200 to the plurality of pixels PX. The supply voltage may be at least one of a driving voltage, an initialization voltage, a reference voltage, and a low-level voltage. The plurality of voltage lines VL may extend in the second direction (y-axis direction) and may be spaced apart from each other in the first direction (x-axis direction).

The non-display area NDA may surround the display area DA. In the non-display area NDA, the gate driver 210, fan-out lines FOL, and gate control lines GCL may be disposed. The gate driver 210 may generate a plurality of gate signals based on the gate control signal and may sequentially supply the plurality of gate signals to the plurality of gate lines GL in a predetermined order.

The fan-out lines FOL may extend from the display driver 200 to the display area DA. The fan-out lines FOL may supply the data voltage received from the display driver 200 to the plurality of data lines DL.

A gate control line GCL may extend from the display driver 200 to the gate driver 210. The gate control line GCL may supply the gate control signal received from the display driver 200 to the gate driver 210.

The subsidiary area SBA may include the display driver 200 and a pad area DPA.

The display driver 200 may output signals and voltages for driving the display panel 100 to the fan-out lines FOL. The display driver 200 may supply data voltages to the data lines DL through the fan-out lines FOL. The data voltages may be applied to the plurality of pixels PX, in association with controlling the luminance of the plurality of pixels PX. The display driver 200 may supply a gate control signal to the gate driver 210 through the gate control lines GCL.

The pad area DPA may be disposed at an edge of the subsidiary area SBA. The pad area DPA may be electrically connected to the circuit board 300 using a material such as, for example, an anisotropic conductive film and a self-assembly anisotropic conductive paste (SAP).

The pad area DPA may include a plurality of display pads DP. The display pads DP may be connected to a graphic system through the circuit board 300. The plurality of display pads DP may be connected to the circuit board 300 to receive digital video data and may supply the digital video data to the display driver 200.

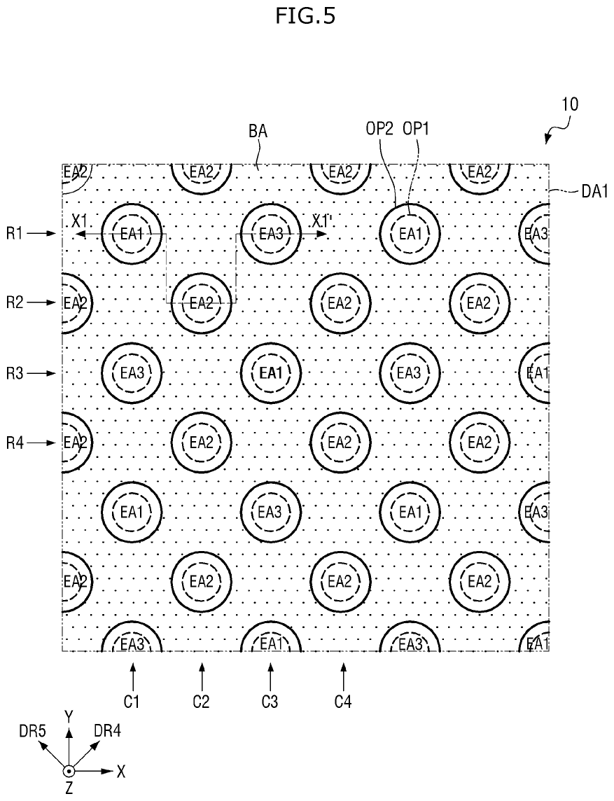

FIG. 5 is a plan view showing an arrangement of emission areas in a first display area of a display device according to an embodiment.

Referring to FIG. 5, the display device 10 may include a plurality of emission areas EA1, EA2, and EA3 and non-emission areas BA arranged in the display area DA. The display area shown in FIG. 5 is the first display area DA1, and a plurality of emission areas EA1, EA2, and EA3 may be located in the first display area DA1. It should be understood, however, that a plurality of emission areas EA1, EA2, and EA3 may be located in the second display area DA2 and the third display area DA3 of the display area DA.

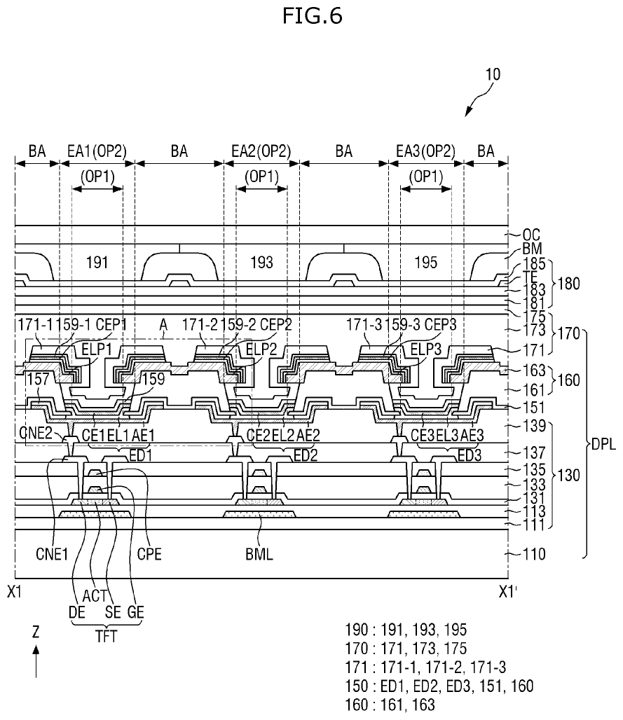

The emission areas EA1, EA2, and EA3 may include first emission areas EA1, second emission areas EA2, and third emission areas EA3 that emit light of different colors. The first to third emission areas EA1, EA2, and EA3 may emit red light, green light, and blue light, respectively. The colors of light respectively emitted from the emission areas EA1, EA2, and EA3 may be based on the type of light-emitting elements ED1, ED2, and ED3 (see FIG. 6) disposed in the emission material layer 150 to be described later herein. According to an embodiment of the present disclosure, the first emission area EA1 emits first light of red color, the second emission area EA2 emits second light of green color, and the third emission area EA3 emits third light of blue color. It is, however, to be understood that the present disclosure is not limited thereto. For example, the first emission area EA1, the second emission area EA2, and/or the third emission area EA3 may be configured to emit light different from the light described herein.

The emission areas EA1, EA2, and EA3 may be arranged in a PenTile™ matrix, for example, a diamond PenTile™ matrix. For example, the first emission area EA1 and the third emission area EA3 may be spaced apart from each other in the first direction (x-axis direction) and may be arranged alternately in the first direction (x-axis direction) and the second direction (y-axis direction). With regard to the emission areas EA1, EA2, and EA3, the first emission area EA1 and the third emission area EA3 may be arranged alternately in the first direction (x-axis direction) in the first row R1 and the third row R3. In the first column C1 and the third column C3, the first emission area EA1 and the third emission area EA3 may be arranged alternately in the second direction (y-axis direction).

A second emission area EA2 may be spaced apart from another adjacent second emission area EA2 in the first direction (x-axis direction) and the second direction (y-axis direction), and the second emission area EA2 may be spaced apart from an adjacent first emission area EA1 and a third emission area EA3 in a fourth direction DR4 or a fifth direction DR5. A plurality of second emission areas EA2 may be repeatedly arranged in the first direction (x-axis direction) and the second direction (y-axis direction), and the second emission area EA2 and the first emission area EA1, or the second emission area EA2 and the third emission area EA3 may be arranged alternately in the fourth direction DR4 or the fifth direction DR5. With regard to the arrangement of the emission areas EA1, EA2, and EA3, second emission areas EA2 may be arranged repeatedly in the first direction (x-axis direction) in the second row R2 and the fourth row R4, and second emission areas EA2 may arranged be repeatedly in the second direction (y-axis direction) in the second column C2 and the fourth column C4.

Each of the first to third emission areas EA1, EA2, and EA3 may be defined by a first opening OP1 and a second opening OP2 formed by an inorganic pixel-defining layer 151 (see FIG. 6) and a bank structure 160 (see FIG. 6) of the emission material layer 150, which will be described later herein.

The non-emission areas BA may be located around the emission areas EA1, EA2, and EA3. For example, the non-emission areas BA may surround the emission areas EA1, EA2, and EA3 (e.g., with reference to the XY plane). In the non-emission areas BA, no light passes. For example, and a light-blocking layer BM (see FIG. 6) and the inorganic pixel-defining layer 151 may overlap the non-emission areas BA.

FIG. 6 is a cross-sectional view of a portion of the display device 10 according to an embodiment, showing cross-sections of the display layer DPL, the touch sensing layer 180, and the color filter layer 190.

Referring to FIG. 6, the display layer DPL may include a substrate 110, a thin-film transistor layer 130, an emission material layer 150, and a thin-film encapsulation layer 170.

The substrate 110 has been described herein, and repeated descriptions of the substrate 110 are omitted for brevity.

The thin-film transistor layer 130 may include a first buffer layer 111, a bottom metal layer BML, a second buffer layer 113, a thin-film transistor TFT, a gate insulating layer 131, a first interlayer dielectric layer 133, a capacitor electrode CPE, a second interlayer dielectric layer 135, a first connection electrode CNE1, a planarization layer 137, a second connection electrode CNE2 and a via layer 139.

The first buffer layer 111 may be disposed on the substrate 110. The first buffer layer 111 may include an inorganic film capable of preventing permeation of air or moisture. For example, the first buffer layer 111 may include a plurality of inorganic films stacked on one another alternately.

The bottom metal layer BML may be disposed on the first buffer layer 111. For example, the bottom metal layer BML may be a single layer or a multilayer formed of any one or more of molybdenum (Mo), aluminum (Al), chromium (Cr), gold (Au), titanium (Ti), nickel (Ni), neodymium (Nd) and copper (Cu), and alloys thereof.

The second buffer layer 113 may cover the first buffer layer 111 and the bottom metal layer BML. The second buffer layer 113 may include an inorganic film capable of preventing permeation of air or moisture. For example, the second buffer layer 113 may include a plurality of inorganic films stacked on one another alternately.

The thin-film transistor TFTs may be disposed on the second buffer layer 113 and may form respective pixel circuits of a plurality of pixels. For example, each thin-film transistor TFT may be a driving transistor or a switching transistor of a pixel circuit. Each thin-film transistor TFT may include a semiconductor layer ACT, a source electrode SE, a drain electrode DE and a gate electrode GE.

The semiconductor layer ACT may be disposed on the second buffer layer 113. The semiconductor layer ACT may overlap the bottom metal layer BML and the gate electrode GE in the thickness direction and may be insulated from the gate electrode GE by the gate insulating layer 131. The material of a portion of the semiconductor layer ACT may be made conductive to form the source electrode SE and the drain electrode DE.

The gate electrode GE may be disposed on the gate insulating layer 131. The gate electrode GE may overlap the semiconductor layer ACT with the gate insulating layer 131 interposed between the gate electrode GE and the semiconductor layer ACT.

The gate insulating layer 131 may be disposed on the semiconductor layer ACT. For example, the gate insulating layer 131 may cover the semiconductor layer ACT and the second buffer layer 113, and may insulate the semiconductor layer ACT from the gate electrode GE. The gate insulating layer 131 may include a contact hole through which the first connection electrode CNE1 passes.

The first interlayer dielectric layer 133 may cover the gate electrode GE and the gate insulating layer 131. The first interlayer dielectric layer 133 may include a contact hole through which the first connection electrode CNE1 passes. The contact hole of the first interlayer dielectric layer 133 may be connected to the contact hole of the gate insulating layer 131 and a contact hole of the second interlayer dielectric layer 135.

The capacitor electrode CPE may be disposed on the first interlayer dielectric layer 133. The capacitor electrode CPE may overlap with the gate electrode GE in the thickness direction (e.g., in the X direction or the Y direction). The capacitor electrode CPE and the gate electrode GE may form a capacitance.

The second interlayer dielectric layer 135 may cover the capacitor electrode CPE and the first interlayer dielectric layer 133. The second interlayer dielectric layer 135 may include a contact hole through which the first connection electrode CNE1 passes. The contact hole of the second interlayer dielectric layer 135 may be connected to the contact hole of the first interlayer dielectric layer 133 and the contact hole of the gate insulating layer 131.

The first connection electrodes CNE1 may be disposed on the second interlayer dielectric layer 135. Each first connection electrode CNE1 may electrically connect the drain electrode DE of a thin-film transistor TFT with a second connection electrode CNE2. The first connection electrode CNE1 may be inserted into a contact hole formed in the second interlayer dielectric layer 135, the first interlayer dielectric layer 133, and the gate insulating layer 131 to be in contact with the drain electrode DE of the thin-film transistor TFT.

The planarization layer 137 may cover the first connection electrode CNE1 and the second interlayer dielectric layer 135. The planarization layer 137 can protect the thin-film transistor TFT. The planarization layer 137 may include a contact hole through which the second connection electrode CNE2 passes.

The second connection electrodes CNE2 may be disposed on the planarization layer 137. The second connection electrodes CNE2 may respectively electrically connect the first connection electrodes CNE1 with the pixel electrodes AE1, AE2 and AE3 of the light-emitting elements ED1, ED2 and ED3. For example, each second connection electrode CNE2 may be inserted into a contact hole formed in the planarization layer 137 to be in contact with a respective first connection electrode CNE1.

The via layer 139 may cover the second connection electrodes CNE2 and the planarization layer 137. The via layer 139 may include contact holes through which the pixel electrodes AE1, AE2 and AE3 of the light-emitting elements ED1, ED2 and ED3 pass.

The via layer 139 may be formed of an insulating material. For example, the via layer 139 may be formed of a single layer or multiple layers of an inorganic material, an organic material, or an organic/inorganic composite, and may be formed by various deposition methods. In some embodiments, the via layer 139 may be formed of any one or more of polyacrylates resin, epoxy resin, phenolic resin, polyamides resin, polyimides resin, unsaturated polyesters resin, poly phenylenethers resin, poly phenylene sulfides resin, benzocyclobutene (BCB), or the like. In some embodiments, the via layer 139 may be formed of one or more materials selected from the group consisting of polyacrylates resin, epoxy resin, phenolic resin, polyamides resin, polyimides resin, unsaturated polyesters resin, poly phenylenethers resin, poly phenylene sulfides resin, and benzocyclobutene (BCB). Additionally, or alternatively, the via layer 139 may include an organic protective film such as, for example, a planarization film that is transparent and has fluidity supportive of alleviating and flattening the curvature of the underlying structures.

The emission material layer 150 may be disposed on the thin-film transistor layer 130. The emission material layer 150 may include light-emitting elements ED1, ED2 and ED3, an inorganic pixel-defining layer 151, and a plurality of bank structures 160. The light-emitting elements ED1, ED2 and ED3 may include the pixel electrodes AE1, AE2 and AE3, the emissive layers EL1, EL2 and EL3, and the common electrodes CE1, CE2 and CE3, respectively.

The display device 10 may include a plurality of emission areas EA1, EA2, and EA3 arranged in the display area DA. In some embodiments, the first to third emission areas EA1, EA2, and EA3 may have the same area or size. For example, the second openings OP2 by the bank structure 160 in the first emission area EA1, the second emission area EA2, and the third emission area EA3 may have the same diameter. It should be understood, however, that the present disclosure is not limited thereto. For example, respective areas or sizes of the first to third emission areas EA1, EA2, and EA3 of the display device 10 may be different from one another. For example, the area of the second emission area EA2 may be larger than the areas of the first emission area EA1 and the third emission area EA3, and the area of the third emission area EA3 may be larger than the area of the first emission area EA1. The intensity of light respectively emitted from the emission areas EA1, EA2, and EA3 may be based on the size of the emission areas EA1, EA2, and EA3. The colors of the images displayed on the display device 10 or the electronic device 1 can be controlled by adjusting the size of the emission areas EA1, EA2, and EA3. That is to say, for example, the size of the emission areas EA1, EA2, and EA3 may be adjusted as desired according to the colors of the images to be provided by the display device 10 and the electronic device 1.

One first emission area EA1, one second emission area EA2 and one third emission area EA3 disposed adjacent to one another may form a pixel group. The pixel group may represent black-and-white or grayscales by emitting light of different colors at the emission areas EA1, EA2, and EA3. It should be understood, however, that the present disclosure is not limited thereto. The combination of the emission areas EA1, EA2, and EA3 forming a single pixel group may be modified depending on the arrangement of the emission areas EA1, EA2, and EA3 and the colors of the light emitted from the emission areas EA1, EA2, and EA3.

The pixel electrodes AE1, AE2 and AE3 may be disposed on the via layer 139. The pixel electrodes AE1, AE2 and AE3 may be electrically connected to the drain electrode DE of the thin-film transistor TFT through the first and second connection electrodes CNE1 and CNE2.

The pixel electrodes AE1, AE2 and AE3 may be disposed in the emission areas EA1, EA2, and EA3, respectively. The pixel electrodes AE1, AE2 and AE3 may include a first pixel electrode PE1 disposed in the first emission area EA1, the second pixel electrode PE2 disposed in the second emission area EA2, and the third pixel electrode PE3 disposed in the third emission area EA3. The pixel electrodes AE1, AE2 and AE3 may be spaced apart from one another by the via layer 139. Specifically, the pixel electrodes AE1, AE2 and AE3 may be disposed in different emission areas EA1, EA2, and EA3, respectively, to form light-emitting elements ED1, ED2 and ED3 emitting light of different colors.

According to an embodiment of the present disclosure, the pixel electrodes AE1, AE2 and AE3 may have a stack structure of a material layer having a high work function (e.g., greater than or equal to a target threshold work function) such as, for example, indium-tin-oxide (ITO), indium-zinc-oxide (IZO), zinc oxide (ZnO) and indium oxide (In₂O₃), and a reflective material layer such as, for example, silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or a mixture thereof. In some embodiments, for the pixel electrodes AE1, AE2 and AE3, layers having a higher work function may be disposed on a higher layer than reflective material layers such that the layers having the higher work function are respectively closer (e.g., in the Z direction) to the emissive layers EL1, EL2 and EL3. Non-limiting examples of the pixel electrodes AE1, AE2 and AE3 include multilayer structures of ITO/Mg, ITO/MgF, ITO/Ag, and ITO/Ag/ITO.

The inorganic pixel-defining layer 151 may overlap the non-emission areas BA and may be disposed on the pixel electrodes AE1, AE2 and AE3 and the via layer 139.

According to some embodiments, the inorganic pixel-defining layer 151 may define a plurality of first openings OP1 forming the emission areas EA1, EA2, and EA3. The inorganic pixel-defining layer 151 may expose the pixel electrodes AE1, AE2 and AE3 at locations where the inorganic pixel-defining layer 151 overlaps the first openings OP1.

The inorganic pixel-defining layer 151 (also referred to as an inorganic pixel-defining film) may include an inorganic insulating material. For example, the inorganic pixel-defining layer 151 may include any one or more of aluminum oxide, titanium oxide, tantalum oxide, hafnium oxide, zinc oxide, silicon oxide, silicon nitride, and silicon oxynitride.

The bank structure 160 may be disposed on the inorganic pixel-defining layer 151. The bank structure 160 may define a plurality of second openings OP2 forming the emission areas EA1, EA2, and EA3. The light-emitting elements ED1, ED2 and ED3 of the display device 10 may be in line with the second openings OP2 of the bank structure 160. The bank structure 160 may include a first bank layer 161 and a second bank layer 163 that include different metal materials and structures to perform different functions.

The emissive layers EL1, EL2 and EL3 may be disposed on the pixel electrodes AE1, AE2 and AE3, respectively. The emissive layers EL1, EL2 and EL3 may be organic emissive layers formed of organic materials and may be formed on the pixel electrodes AE1, AE2 and AE3 via a deposition process. In an example in which the thin-film transistor TFT applies a predetermined voltage to the pixel electrodes AE1, AE2 and AE3 of the light-emitting elements ED1, ED2 and ED3 and the common electrode CE of the light-emitting elements ED1, ED2 and ED3 receives a common voltage or cathode voltage, holes and electrons may move to the emissive layers EL1, EL2 and EL3 through the hole transporting layer and the electron transporting layer, respectively, and the holes and electrons combine in the emissive layers EL1, EL2 and EL3 to emit light.

The emissive layers EL1, EL2 and EL3 may include a first emissive layer EL1, a second emissive layer EL2, and a third emissive layer EL3 disposed in different emission areas EA1, EA2, and EA3. The first emissive layer EL1 may be disposed on the first pixel electrode AE1 in the first emission area EA1, the second emissive layer EL2 may be disposed on the second pixel electrode AE2 in the second emission area EA2, and the third emissive layer EL3 may be disposed on the third pixel electrode AE3 in the third emission area EA3. The first to third emissive layers EL1, EL2 and EL3 may be the emissive layers of the first to third light-emitting elements ED1, ED2 and ED3, respectively. The first emissive layer EL1 may emit light (e.g., red light) of a first color, the second emissive layer EL2 may emit light (e.g., green light) of a second color, and the third emissive layer EL3 may emit light (e.g., blue light) of a third color.

According to some embodiments of the present disclosure, the emissive layers EL1, EL2 and EL3 may be partially disposed between the pixel electrodes AE1, AE2 and AE3 and the inorganic pixel-defining layer 151. For example, respective portions of the emissive layers EL1, EL2 and EL3 may be disposed between the pixel electrodes AE1, AE2 and AE3 and the inorganic pixel-defining layer 151. The inorganic pixel-defining layer 151 may be disposed on the pixel electrodes AE1, AE2 and AE3 and may be spaced apart from the upper surfaces of the pixel electrodes AE1, AE2 and AE3. In some embodiments, the deposition process of the emissive layers EL1, EL2 and EL3 may be conducted such that the material of the emissive layers EL1, EL2 and EL3 is deposited in an inclined direction with respect to the upper surface of the substrate 110, rather than (or in addition to) in a direction perpendicular to the upper surface of the substrate 110. By depositing the material of the emissive layers EL1, EL2 and EL3 in an inclined direction, the emissive layers EL1, EL2 and EL3 may be disposed on the upper surfaces of the pixel electrodes AE1, AE2 and AE3 exposed through the second openings OP2 of the bank structure 160, and the emissive layers EL1, EL2 and EL3 may fill the spaces between the pixel electrodes AE1, AE2 and AE3 and the inorganic pixel-defining layer 151. A deposition process of the emissive layers EL1, EL2 and EL3 will be described in detail later herein.

A temporary protective layer may be disposed between the inorganic pixel-defining layer 151 and the pixel electrodes AE1, AE2 and AE3 and removed in the process of fabricating the display device 10. In an example, the emissive layers EL1, EL2 and EL3 may be disposed in regions or gaps corresponding to where the temporary protective layer is partially removed, and thus, the lower surface of the inorganic pixel-defining layer 151 may be spaced apart from the pixel electrodes AE1, AE2 and AE3. Portions of the temporary protective layer that are not removed may remain as a residual pattern layer 157 between the inorganic pixel-defining layer 151 and the pixel electrodes AE1, AE2 and AE3. Accordingly, the regions or gaps between the inorganic pixel-defining layer 151 and the pixel electrodes AE1, AE2 and AE3 may be filled with the residual pattern layer 157 and the emissive layers EL1, EL2 and EL3.

The common electrodes CE1, CE2 and CE3 may be disposed on the emissive layers EL1, EL2 and EL3. The common electrodes CE1, CE2 and CE3 include a transparent conductive material to allow light generated in the emissive layers EL1, EL2 and EL3 to exit. The common electrodes CE1, CE2 and CE3 may receive a common voltage or a low-level voltage. When the pixel electrodes AE1, AE2 and AE3 receive the voltage equal to the data voltage and the common electrodes CE1, CE2 and CE3 receive the low-level voltage, a potential difference may be formed between the pixel electrodes AE1, AE2 and AE3 and the common electrodes CE1, CE2 and CE3, such that the emissive layers EL1, EL2 and EL3 may emit light.

For example, the common electrodes CE1, CE2 and CE3 may include, but are not limited to, silver (Ag). The common electrodes CE1, CE2 and CE3 may each include a material layer having a small work function (e.g., below a target threshold work function) such as, for example, Li, Ca, LiF/Ca, LiF/Al, Al, Mg, Pt, Pd, Ni, Au, Nd, Ir, Cr, BaF and Ba, or a compound or mixture thereof (e.g., a mixture of Ag and Mg). The common electrodes CE1, CE2 and CE3 may each further include a transparent metal oxide layer disposed on the material layer having a small work function.

The common electrodes CE1, CE2 and CE3 may include a first common electrode CE1, a second common electrode CE2 and a third common electrode CE3 respectively disposed in different emission areas EA1, EA2, and EA3. The first common electrode CE1 may be disposed on the first emissive layer EL1 in the first emission area EA1, the second common electrode CE2 may be disposed on the second emissive layer EL2 in the second emission area EA2, and the third common electrode CE3 may be disposed on the third emissive layer EL3 in the third emission area EA3.

In the display device 10 according to an embodiment of the present disclosure, the common electrodes CE1, CE2 and CE3 disposed in the different emission areas EA1, EA2, and EA3 may be indirectly connected. For example, the common electrodes CE1, CE2 and CE3 disposed in the different emission areas EA1, EA2, and EA3 are not directly connected, but may be electrically connected through the first bank layer 161 of the bank structure 160. Accordingly, portions of the common electrodes CE1, CE2 and CE3 may be disposed on the side surfaces of the first bank layer 161 of the bank structure 160.

A capping layer 159 may be disposed on the common electrodes CE1, CE2 and CE3. The capping layer 159 may include an inorganic insulating material to cover the light-emitting elements ED1, ED2 and ED3 and patterns disposed on the bank structure 160. The capping layer 159 can prevent the light-emitting elements ED1, ED2 and ED3 from being damaged by outside air and can prevent the patterns disposed on the bank structure 160 from being delaminated during the process of fabricating the display device 10. In an embodiment, the capping layer 159 may include any one or more of aluminum oxide, titanium oxide, tantalum oxide, hafnium oxide, zinc oxide, silicon oxide, silicon nitride, and silicon oxynitride.

The thin-film encapsulation layer 170 may be disposed on the light-emitting elements ED1, ED2, and ED3 and the bank structure 160, and may cover the plurality of light-emitting elements ED1, ED2 and ED3 and the bank structure 160. The thin-film encapsulation layer 170 may include at least one inorganic film capable of reducing or preventing permeation of oxygen or moisture into the emission material layer 150. The thin-film encapsulation layer 170 may include at least one organic film capable of protecting the emission material layer 150 from foreign substances such as, for example, dust. According to an embodiment of the present disclosure, the thin-film encapsulation layer 170 may include a first encapsulation layer 171, a second encapsulation layer 173, and a third encapsulation layer 175 sequentially stacked on one another. In an example, the first encapsulation layer 171 and the third encapsulation layer 175 may be inorganic encapsulation layers, and the second encapsulation layer 173 disposed therebetween may be an organic encapsulation layer. Additionally, or alternatively, the first encapsulation layer 171, the second encapsulation layer 173, and the third encapsulation layer 175 may include any suitable combination of inorganic and/or organic encapsulation layers.

Each of the first encapsulation layer 171 and the third encapsulation layer 175 may include one or more inorganic insulating materials. The inorganic insulating materials may include any one or more of aluminum oxide, titanium oxide, tantalum oxide, hafnium oxide, zinc oxide, silicon oxide, silicon nitride, and silicon oxynitride.

The second encapsulation layer 173 may include a polymer-based material. The polymer-based material may include any one or more of an acrylic resin, an epoxy resin, polyimide, polyethylene, and the like. For example, the second encapsulation layer 173 may include any one or more of an acrylic resin, e.g., polymethyl methacrylate, polyacrylic acid, or the like. The second encapsulation layer 173 may be formed by curing a monomer or by applying a polymer.

The first encapsulation layer 171 may include a first inorganic layer 171-1, a second inorganic layer 171-2, and a third inorganic layer 171-3 disposed in the different emission areas EA1, EA2, and EA3, respectively.

The touch sensing layer 180 may be disposed on the thin-film encapsulation layer 170. The touch sensing layer 180 may include a touch buffer layer 181, a touch insulating layer 183 (also referred to herein as a touch insulation layer), touch electrodes TE, and a touch protective layer 185.

The touch buffer layer 181 may be disposed on the thin-film encapsulation layer 170. The touch buffer layer 181 may be insulating and support optical functions. The touch buffer layer 181 may include at least one inorganic film. Optionally, the touch buffer layer 181 may be omitted. Although not shown in the drawings, in some embodiments, the connection electrodes electrically connecting between the touch electrodes may be disposed on the touch buffer layer 181. The connection electrodes may be formed of a single layer of molybdenum (Mo), titanium (Ti), copper (Cu), aluminum (Al), or indium tin oxide (ITO). Additionally, or alternatively, the connection electrodes may be formed of a stack structure of aluminum and titanium (Ti/Al/Ti), a stack structure of aluminum and ITO (ITO/AI/ITO), an APC alloy, or a stack structure of an APC alloy and ITO (ITO/APC/ITO).

The touch insulating layer 183 may cover the touch buffer layer 181. The touch insulating layer 183 may have insulating functions. For example, the touch insulating layer 183 may be an inorganic layer including any one or more of a silicon nitride layer, a silicon oxynitride layer, a silicon oxide layer, a titanium oxide layer, an aluminum oxide layer, or the like. In some examples, the touch insulating layer 183 may be an inorganic layer including at least one selected from the group consisting of: a silicon nitride layer, a silicon oxynitride layer, a silicon oxide layer, a titanium oxide layer and an aluminum oxide layer.

In some aspects, some of the touch electrodes TE may be disposed on the touch insulating layer 183. In an example, the touch electrodes TE may not overlap with the first to third emission areas EA1, EA2, and EA3. The touch electrodes TE may be formed of a single layer of molybdenum (Mo), titanium (Ti), copper (Cu), aluminum (Al), or indium tin oxide (ITO). Additionally, or alternatively, the touch electrodes TE may be formed of a stack structure of aluminum and titanium (Ti/Al/Ti), a stack structure of aluminum and ITO (ITO/Al/ITO), an APC alloy, or a stack structure of an APC alloy and ITO (ITO/APC/ITO).

The touch protective layer 185 may cover the touch electrodes TE and the touch insulating layer 183. The touch protective layer 185 may have insulating properties and optical functions. The touch protective layer 185 may be formed of any of the materials described herein with reference to forming the touch insulating layer 183.

A light-blocking layer BM may be disposed on the touch sensing layer 180. The light-blocking layer BM may overlap the non-emission area BA. In some examples, the light-blocking layer BM may partially overlap the non-emission area BA. Accordingly, for example, the light-blocking layer BM may overlap the via layer 139, the inorganic pixel-defining layer 151 and the bank structure 160. The light-blocking layer BM may include a light-absorbing material. For example, the light-blocking layer BM may include an inorganic black pigment or an organic black pigment. The inorganic black pigment may be, but is not limited to, carbon black, and the organic black pigment may include, but is not limited to, at least one of lactam black, perylene black, and aniline black. The light-blocking layer BM can prevent visible light from penetrating between the first to third emission areas EA1, EA2, and EA3 to improve the color gamut of the display device 10. For example, the light-blocking layer BM may prevent the mixing of colors respectively emitted by the first to third emission areas EA1, EA2, and EA3.

The color filter layer 190 may overlap with the emission areas EA1, EA2, and EA3 and may be disposed on the touch protective layer 185 and the light-blocking layer BM.

The color filter layer 190 may include a first color filter 191, a second color filter 193 and a third color filter 195 disposed in different emission areas EA1, EA2, and EA3, respectively. The color filters 191, 193 and 195 may each include a colorant such as, for example, a dye and pigment that absorbs light in wavelength ranges other than light in a particular wavelength range, and may be disposed in association with the light exiting from the emission areas EA1, EA2, and EA3. For example, the first color filter 191 may be a red color filter that transmits first red light (e.g., only first red light), and the color filters 191 is disposed such that the first color filter 191 overlaps with the first emission area EA1. The second color filter 193 may be a green color filter that transmits green second light (e.g., only green second light), and the second color filter 193 is disposed such that the second color filter 193 overlaps with the second emission area EA2. The third color filter 195 may be a blue color filter that transmits blue third light (e.g., only blue third light), and the third color filter 195 is disposed such that the third color filter 195 overlaps with the third emission area EA3.

The color filters 191, 193 and 195 may partially overlap with one another (e.g., in a direction crossing the Z direction), for example, in regions which do not overlap the light-blocking layer BM. The different color filters 191, 193 and 195 may not overlap with other emission areas among the emission areas EA1, EA2, and EA3 and may overlap with one another on the light-blocking layer BM. In an example implementation, the second color filter 193 overlaps the emission area EA2 but does not overlap another emission area (e.g., emission area EA1, emission area EA3).

The overcoat layer OC may be disposed over the color filter layer 190 and the light-blocking layer BM to provide a flat surface over the color filters 191, 193 and 195. The overcoat layer OC may be a colorless light-transmitting layer having no color in the visible light band. For example, the overcoat layer OC may include a colorless light-transmitting organic material such as, for example, an acryl-based resin.

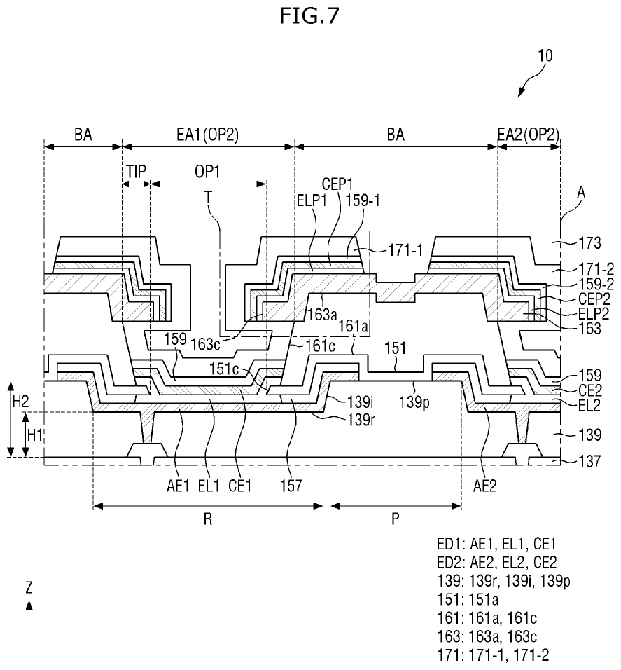

FIG. 7 is an enlarged cross-sectional view of area A of FIG. 6.

Referring to FIG. 7, the via layer 139 may include a recess R depressed toward the substrate 110 in line with the emission areas EA1, EA2, and EA3. For example, with reference to FIG. 7, a center of the recess R may be aligned with a center of emission area EA1, and the recess R may completely overlap the emission area EA1. Alternatively or additionally, the via layer 139 may include a protrusion P protruding toward the bank structure 160 in line with the non-emission area BA. For example, a center of the protrusion P may be aligned with a center of the bank structure 160, and the protrusion P may overlap a portion of the bank structure 160. In other words, the via layer 139 may include recesses and protrusions repeated in a direction parallel to the substrate 110 (e.g., in a direction perpendicular to the Z direction).

In some embodiments, the thickness H1 of the recess R of the via layer 139 may be smaller than the thickness H2 of other portions (e.g., protrusion P) of the via layer 139. In other words, the thickness H2 of the protrusion P of the via layer 139 may be larger than the thickness H1 of other portions (e.g., recess R) of the via layer 139.

In some embodiments, the via layer 139 may include a flat surface 139r that overlaps the recess R and in contact with the first pixel electrode AE1, and a flat surface 139p that overlaps the protrusion P and in contact with the first pixel electrode AE1 and the inorganic pixel-defining layer 151. The flat surface 139r overlapping the recess R and the flat surface 139p overlapping the protrusion P may include a step. Accordingly, the flat surface 139r overlapping the recess R and the flat surface 139p overlapping the protrusion P may be connected by an inclined surface 139i positioned therebetween.

In some embodiments, the first pixel electrode AE1 may be positioned in the recess R of the via layer 139 and in contact with the flat surface 139r of the via layer 139. In addition, the first pixel electrode AE1 may overlap the non-emission area BA, cover the inclined surface 139i, and at least partially cover the flat surface 139p of the via layer 139. Accordingly, the first pixel electrode AE1 may overlap a stepped portion along the inclined surface 139i of the via layer 139.

As shown in FIG. 7, the second pixel electrode AE2 may be spaced apart from the first pixel electrode AE1 in a direction parallel to the substrate 110 (e.g., a direction perpendicular to the Z-direction) by the via layer 139. For example, the first pixel electrode AE1 and the second pixel electrode AE2 may be spaced apart from each other on the flat surface 139p of the via layer 139. Although the first pixel electrode AE1 has been described for convenience of illustration, the respective structures of the pixel electrodes AE2 and AE3 may include the described aspects of the structure of the pixel electrode AE1. For example, the pixel electrodes AE1, AE2, and AE3 may all have the same structure. Additionally, or alternatively, respective structures of the pixel electrodes AE1, AE2, and AE3 may differ at least partially.

The inorganic pixel-defining layer 151 may overlap the non-emission area BA and may be disposed on the via layer 139. The inorganic pixel-defining layer 151 may cover the first pixel electrode AE1 and the second pixel electrode AE2 on the via layer 139. Accordingly, for example, the inorganic pixel-defining layer 151 may include a step along the inclined surface 139i of the via layer 139. The inorganic pixel-defining layer 151 may be in contact with a portion of the flat surface 139p of the via layer 139 where (e.g., in a region where) the first pixel electrode AE1 is spaced apart from the second pixel electrode AE2.

The first opening OP1 defined by the inorganic pixel-defining layer 151 may overlap the recess R of the via layer 139. In an example, the width of the first opening OP1 defined by the inorganic pixel-defining layer 151 may be smaller than the width of the recess R of the via layer 139. Accordingly, for example, the first emissive layer EL1, the first common electrode CE1, and the capping layer 159 positioned in the first opening OP1 may overlap the recess R of the via layer 139. According to one or more embodiments of the present disclosure, the emissive layers EL1, EL2 and EL3, the common electrodes CE1, CE2 and CE3, and the capping layer 159 positioned in the first opening OP1, second opening OP2, and third opening OP3 may overlap respective recesses R of the via layer 139.

In some embodiments, a side surface 151c of the inorganic pixel-defining layer 151 facing the first opening OP1 may overlap the recess R of the via layer 139. In some aspects, the side surface 151c of the inorganic pixel-defining layer 151 may overlap the protrusion P of the via layer 139 in a direction parallel to the substrate 110 in the recess R of the via layer 139.

Referring to FIGS. 6 and 7, the residual pattern layer 157 may be disposed between the inorganic pixel-defining layer 151 and the pixel electrodes AE1, AE2 and AE3. As described herein, in the display device 10, a temporary protective layer may be disposed between the inorganic pixel-defining layer 151 and the pixel electrodes AE1, AE2 and AE3 and then partially removed during the fabrication process. The portion of the temporary protective layer that is not removed may remain in the display device 10 in the form of a residual pattern layer 157. Accordingly, the residual pattern layers 157 disposed in the emission areas EA1, EA2, and EA3, respectively, may be located in contact with the emissive layers EL1, EL2, and EL3 and between the inorganic pixel-defining layer 151 and the pixel electrodes AE1, AE2 and AE3. In other words, the residual pattern layer 157 may overlap the recess R of the via layer 139 and may be in contact with the emissive layers EL1, EL2 and EL3.

In some embodiments, the residual pattern layer 157 may cover or be disposed along the pixel electrodes AE1, AE2 and AE3. Accordingly, the residual pattern layer 157 may include a step along the inclined surface 139i of the via layer 139.

As shown in FIG. 7, the residual pattern layer 157 overlapping the second emission area EA2 may be spaced apart from the residual pattern layer 157 overlapping the first emission area EA1 in a direction perpendicular to the substrate 110 on the flat surface 139p of the via layer 139.

The first bank layer 161 included in the bank structure 160 may be disposed on the inorganic pixel-defining layer 151. The first bank layer 161 may include a first surface 161a in contact with the inorganic pixel-defining layer 151 and a side surface 161c positioned in a direction toward the first opening OP1. For example, the side surface 161c may face the first opening OP1. The first surface 161a of the first bank layer 161 may cover the inorganic pixel-defining layer 151, along the shape (e.g., curvature, stepped portions) of the inorganic pixel-defining layer 151. Accordingly, the first surface 161a of the first bank layer 161 may include a step along the via layer 139.

The side surface 161c of the first bank layer 161 may be inclined in a direction between a direction parallel to the substrate 110 and the third direction (z-axis direction). In some embodiments, the bank structure 160 may be formed by deposition and etching processes instead of a mask process, and the first bank layer 161 may be formed by a wet etch process. Accordingly, the side surface 161c of the first bank layer 161 may be recessed in a direction perpendicular to the substrate 110 more than the inorganic pixel-defining layer 151, such that the side surface 161c may be formed as an inclined surface toward the direction parallel to the substrate 110 from the third direction (z-axis direction). In an embodiment, the side surface 161c of the first bank layer 161 may overlap the recess R of the via layer 139.

The first bank layer 161 may include a metal having high electrical conductivity (e.g., an electrical conductivity equal to or greater than a threshold value). For example, the first bank layer 161 may include aluminum (Al) having high electrical conductivity. Accordingly, the first bank layer 161 may be electrically connected to the common electrodes CE1, CE2 and CE3.

The second opening OP2 defined by the first bank layer 161 may overlap the recess R of the via layer 139. For example, the width of the second opening OP2 defined by the first bank layer 161 may be smaller than the width of the recess R of the via layer 139. Accordingly, for example, the first emissive layer EL1, the first common electrode CE1, and the capping layer 159 positioned in the second opening OP2 may overlap the recess R of the via layer 139. According to one or more embodiments of the present disclosure, the emissive layers EL1, EL2 and EL3, the common electrodes CE1, CE2 and CE3 and the capping layer 159 positioned in the first opening OP1, second opening OP2, and third opening OP3 may overlap respective recesses R of the via layer 139.

The second bank layer 163 may be disposed on the first bank layer 161. The second bank layer 163 may include a material having a lower etching rate than the first bank layer 161, and for example, the second bank layer 163 may include titanium (Ti).

In some embodiments, the second bank layer 163 may include a first surface 163a facing the first bank layer 161 and a side surface 163c facing the first opening OP1. In the example illustrated at FIG. 7, the side surface 163c may be included in the first opening OP1. Like the first bank layer 161, the second bank layer 163 is formed via a wet etching process. The second bank layer 163 includes a material that is relatively stable during the wet etching process compared to the first bank layer 161, and thus the side surface 163c of the second bank layer 163 may have a shape protruding toward the first opening OP1 more than the side surface 161c of the first bank layer 161. In other words, the side surface 161c of the first bank layer 161 may have a shape depressed inward from the side surface 163c of the second bank layer 163. Expressed another way, the side surface 161c of the first bank layer 161 may be depressed further away from the first opening OP1 compared to the side surface 163c. Accordingly, the second bank layer 163 of the bank structure 160 may include a tip TIP protruding toward the first opening OP1, and an undercut may be formed between the tip TIP of the second bank layer 163 and the side surface 161c of the first bank layer 161. In an embodiment, the tip TIP of the second bank layer 163 may be in line with and disposed in the recess R of the via layer 139. For example, the tip TIP may at least partially overlap the recess R.

In some embodiments, the deposition techniques may mitigate or prevent instances in which a material is not sufficiently deposited under the tip TIP of the bank structure 160 of the display device 10. Accordingly, the materials of the emissive layers EL1, EL2 and EL3 and the common electrodes CE1, CE2 and CE3 may be deposited in an inclined direction rather than in the third direction (z-axis direction) perpendicular to the upper surface of the substrate. For example, the deposition process of forming the emissive layers EL1, EL2 and EL3 may be performed such that the materials are deposited in a direction that is not perpendicular to the upper surface of the pixel electrodes AE1, AE2 and AE3, e.g., in an inclined direction between a direction perpendicular to the substrate 110 and the third direction (z-axis direction). In this manner, the materials can be deposited even under the tip TIP of the bank structure 160.

According to an embodiment of the present disclosure, the angle of the deposition process of forming the emissive layers EL1, EL2 and EL3 is defined as a first angle. The deposition process of forming the emissive layers EL1, EL2 and EL3 may be performed at an angle of 45° to 50° from the upper surface of the pixel electrodes AE1 and AE2 and AE3. That is to say, in some embodiments, the first angle may range from 45° to 50°. Accordingly, for example, by forming the emissive layers EL1, EL2 and EL3 according to the first angle, the emissive layers EL1, EL2 and EL3 may fill the respective spaces between the pixel electrodes AE1, AE2 and AE3 and the inorganic pixel-defining layer 151, and the emissive layers EL1, EL2 and EL3 may be formed on the sidewalls of the second openings OP2 hidden by the protruding tip TIP of the bank structure 160.

The deposition process of forming the common electrodes CE1, CE2 and CE3 may be performed such that the materials are deposited in a direction that is not perpendicular to the upper surface of the pixel electrodes AE1, AE2 and AE3, e.g., in an inclined direction between a direction parallel to the substrate 110 and the third direction (z-axis direction). According to an embodiment of the present disclosure, the angle of the deposition process of forming the common electrodes CE1, CE2 and CE3 is defined as a second angle. The deposition process of forming the common electrodes CE1, CE2 and CE3 may be performed obliquely (e.g., at an angle that is not 90 degrees) with respect to the upper surface of the pixel electrodes AE1 and AE2 and AE3. For example, the deposition process of forming the common electrodes CE1, CE2 and CE3 may respectively be performed by an angle of 30° or less with respect to the upper surfaces of the pixel electrodes AE1 and AE2 and AE3.

In other words, the deposition process of forming the common electrodes CE1, CE2 and CE3 may be performed in a relatively horizontal direction compared to the deposition process of forming the emissive layers EL1, EL2 and EL3. Accordingly, for example, the contact area between the common electrodes CE1, CE2 and CE3 and the side surfaces 161c of the first bank layer 161 may be larger than the contact area between the emissive layers EL1, EL2 and EL3 and the side surfaces 161c of the first bank layer 161. Accordingly, the deposition process of forming the common electrodes CE1, CE2 and CE3 may have higher step coverage characteristics (e.g., achieve a higher step coverage) than the deposition process of forming the emissive layers EL1, EL2 and EL3. That is to say, for example, the common electrodes CE1, CE2 and CE3 may be deposited to a higher position on the side surfaces 161c of the first bank layer 161 than the emissive layers EL1, EL2 and EL3.

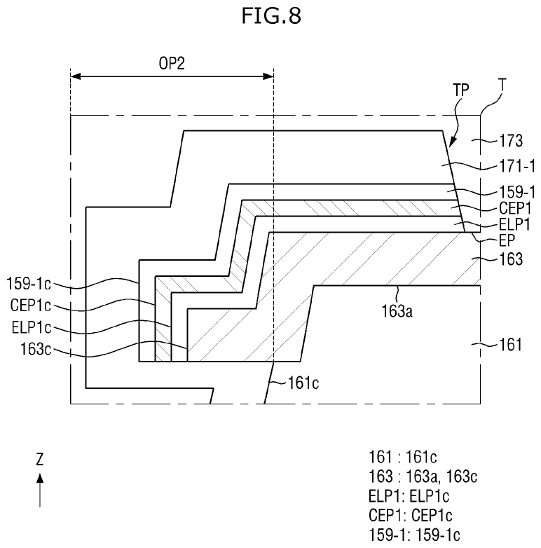

According to one or more embodiments of the present disclosure, the tip TIP of the second bank layer 163 may be formed parallel to the first anode electrode AE1 overlapping the first opening OP1. In other words, the tip TIP of the second bank layer 163 may be formed parallel to the inorganic pixel defining layer 151 overlapping the second opening OP2. That is, the tip TIP of the second bank layer 163 may non-overlap the step included in the inorganic pixel defining layer 151 in the third direction (Z-axis direction). FIG. 8 is an enlarged, cross-sectional view of area T of FIG. 7.

Referring to FIGS. 6 and 8, the display device 10 may include organic patterns ELP1, ELP2 and ELP3, electrode patterns CEP1, CEP2 and CEP3, and capping patterns 159-1, 159-2 and 159-3 disposed on the bank structure 160.

The organic patterns ELP1, ELP2 and ELP3, the electrode patterns CEP1, CEP2 and CEP3, and the capping patterns 159-1, 159-2 and 159-3 may be disposed on the bank structure 160 and may surround the first openings OP1. The stack structures of the organic patterns ELP1, ELP2 and ELP3, the electrode patterns CEP1, CEP2 and CEP3, and the capping patterns 159-1, 159-2 and 159-3 around the first openings OP1 may be partially etched during the process of fabricating the display device 10, such that the pattern shape of the stack structures may be changed. Accordingly, for example, in changing the pattern shape of the stack structures, a portion of the upper surface of the second bank layer 163 of the bank structure 160 may not be covered by the organic patterns ELP1, ELP2 and ELP3, and the uncovered portion is shown as an EP in the FIG. 8. In addition, parts of the organic patterns ELP1, ELP2 and ELP3, and parts of the electrode patterns CEP1, CEP2 and CEP3, and parts of the capping patterns 159-1, 159-2 and 159-3, may form a trench TP.

The plurality of organic patterns ELP1, ELP2 and ELP3 may be disposed on the second bank layer 163 such that the organic patterns ELP1, ELP2 and ELP3 at least partially overlap the second bank layer 163. The organic patterns ELP1, ELP2 and ELP3 may include the same material as the emissive layers EL1, EL2 and EL3 of the light-emitting elements ED1, ED2 and ED3, respectively. The first organic pattern ELP1 may include the same material as the first emissive layer EL1 of the first light-emitting element ED1. The second organic pattern ELP2 may include the same material as the second emissive layer EL2 of the second light-emitting element ED2. The third organic pattern ELP3 may include the same material as the third emissive layer EL3 of the third light-emitting element ED3.

The organic patterns ELP1, ELP2 and ELP3 may be formed as traces that are disconnected from the emissive layers EL1, EL2 and EL3, as the tip TIP included in the bank structure 160 provides physical and electrical separation between organic patterns ELP1, ELP2 and ELP3 and the emissive layers EL1, EL2 and EL3. In the first opening OP1 and the second opening OP2, the emissive layers ELP1, ELP2 and ELP3 may be formed, and the organic patterns ELP1, ELP2 and ELP3 and the emissive layers EL1, EL2 and EL3 may respectively be disconnected from each other by the tip TIP of the bank structure 160.

The first organic pattern ELP1 may include a side surface ELP1c. The side surface ELP1c of the first organic pattern ELP1 covers the side surface 163c of the second bank layer 163 in a region where the first organic pattern ELP1 overlap the second opening OP2. Referring to FIGS. 7 and 8, the first organic pattern ELP1 overlapping the second opening OP2 may overlap the recess R of the via layer 139. Accordingly, the side surface ELP1c of the first organic pattern ELP1 may also overlap the recess R of the via layer 139. Although the first organic pattern ELP1 has been described for convenience of illustration, it is to be understood that organic patterns ELP2 and ELP3 may include the described aspects of the organic pattern ELP1. For example, the organic patterns ELP1, ELP2 and ELP3 all may have the same structure.

The electrode patterns CEP1, CEP2 and CEP3 may be disposed on the organic patterns ELP1, ELP2 and ELP3, respectively. The electrode patterns CEP1, CEP2 and CEP3 may include a first electrode pattern CEP1, a second electrode pattern CEP2, and a third electrode pattern CEP3. The first electrode pattern CEP1, the second electrode pattern CEP2, and the third electrode pattern CEP3 may include the same material as the common electrodes CE1, CE2, and CE3 of the light-emitting elements ED1, ED2 and ED3, respectively. For example, the first electrode pattern CEP1, the second electrode pattern CEP2, and the third electrode pattern CEP3 may be disposed directly on the first organic pattern ELP1, the second organic pattern ELP2, and the third organic pattern ELP3, respectively.

In some embodiments, the arrangement relationship between the electrode patterns CEP1, CEP2, and CEP3 and the organic patterns ELP1, ELP2, and ELP3 may be identical to the arrangement relationship between the emissive layers EL1, EL2 and EL3 of the light-emitting elements ED1, ED2 and ED3 and the common electrodes CE1, CE2, and CE3. For example, the electrode patterns CEP1, CEP2 and CEP3 may be traces that are formed as the deposited material is disconnected from the common electrodes CE1, CE2 and CE3, as the tip TIP included in the bank structure 160 provides physical and electrical separation between the electrode patterns CEP1, CEP2 and CEP3 and the common electrodes CE1, CE2 and CE3. In the display device 10, the techniques described herein support forming the common electrodes CE1, CE2 and CE3 individually in different areas by the tip TIP of the bank structure 160, even in a deposition process without a mask.

The first electrode pattern CEP1 may be located on the first organic pattern ELP1 in a region where the first electrode pattern CEP1 overlaps the second opening OP2. The first electrode pattern CEP1 may include a side surface CEP1c of the first electrode pattern CEP1 covering the side surface ELP1c of the first organic pattern ELP1, in a region where the first electrode pattern CEP1 overlaps the second opening OP2. Referring to FIGS. 7 and 8, the first electrode pattern CEP1 overlapping the second opening OP2 may overlap the recess R of the via layer 139. Accordingly, the side surface CEP1c of the first electrode pattern CEP1 may also overlap the recess R of the via layer 139. Although the first electrode pattern CEP1 has been described for convenience of illustration, it is to be understood that the electrode patterns CEP2 and CEP3 may include the described aspects of the electrode pattern CEP1. For example, the electrode patterns CEP1, CEP2 and CEP3 may all have the same structure. Additionally, or alternatively, respective structures of the electrode patterns CEP1, CEP2 and CEP3 may differ in-part.

The capping patterns 159-1, 159-2 and 159-3 may be disposed on the electrode patterns CEP1, CEP2 and CPE3. The capping patterns 159-1, 159-2 and 159-3 may include the same material as the capping layer 159 disposed on the common electrodes CE1, CE2, and CE3. The capping patterns 159-1, 159-2 and 159-3 may be disposed directly on the first electrode pattern CEP1, the second electrode pattern CEP2, and the third electrode pattern CEP3, respectively. In some embodiments, the arrangement relationship between the capping patterns 159-1, 159-2, and 159-3 and the electrode patterns CEP1, CEP2 and CEP3 may be identical to the arrangement relationship between the common electrodes CE1, CE2 and CE3 of the light-emitting elements ED1, ED2 and ED3 and the capping layer 159. The capping patterns 159-1, 159-2, and 159-3 may be traces that are formed as the deposited material is disconnected from the capping layer 159, as the tip TIP included in the bank structure 160 provides physical and electrical separation between capping patterns 159-1, 159-2, and 159-3 and the capping layer 159.

The first capping pattern 159-1 may include a side surface 159-1c. The side surface 159-1c of the first capping pattern 159-1 covers the side surface CEP1c of the first electrode pattern CEP1 in a region where the first capping pattern 159-1 overlaps the second opening OP2. Referring to FIGS. 7 and 8, the first capping pattern 159-1 overlapping the second opening OP2 may overlap the recess R of the via layer 139. Accordingly, the side surface 159-1c of the first capping pattern 159-1 may also overlap the recess R of the via layer 139. Although the first capping pattern 159-1 is described for convenience of illustration, it is to be understood that the capping patterns 159-2 and 159-3 may include aspects of the capping pattern 159-1 described herein. For example, the capping patterns 159-1, 159-2, and 159-3 may all have the same structure. Additionally, or alternatively, respective structures of the capping patterns 159-1, 159-2 and 159-3 may differ in-part.

In some embodiments, the first to third inorganic layers 171-1, 171-2, and 171-3 included in the first encapsulation layer 171 may respectively cover the common electrodes CE1, CE2, and CE3 and the electrode patterns CEP1, CEP2, and CEP3. In other words, the first to third inorganic layers 171-1, 171-2, and 171-3 may be disposed to cover the light-emitting elements ED1, ED2, and ED3 in the emission areas EA1, EA2, and EA3 or in the second openings OP2 of the bank structure 160. In some embodiments, the first to third inorganic layers 171-1, 171-2 and 171-3 may overlap the non-emission areas BA to cover a plurality of underlying patterns (organic patterns, electrode patterns, and capping patterns).

The first to third inorganic layers 171-1, 171-2, and 171-3 can prevent the light-emitting elements ED1, ED2, and ED3 from being exposed to outside air. The first to third inorganic layers 171-1, 171-2 and 171-3 can prevent the light-emitting elements ED1, ED2 and ED3 from being damaged by outside air and can prevent the patterns disposed on the bank structure 160 from being delaminated during the process of fabricating the display device 10. Since the first to third inorganic layers 171-1, 171-2 and 171-3 may be formed by a chemical vapor deposition method, the first to third inorganic layers 171-1, 171-2, and 171-3 as formed may have a uniform thickness along the step of the deposited layers. For example, the first to third inorganic layers 171-1, 171-2 and 171-3 may be formed as thin films even on the undercut by the tip TIP of the bank structure 160.

Although aspects of the present disclosure support disposing the first to third inorganic layers 171-1, 171-2 and 171-3 in the same layer in the display device 10, the techniques described herein support forming the first to third inorganic layers 171-1, 171-2, and 171-3 via different processes during the process of fabricating the display device 10. For example, in some embodiments, the emissive layers EL1, EL2, and EL3 of the first to third light-emitting elements ED1, ED2, and ED3 may not be formed simultaneously but may be formed via different processes. According to an embodiment of the present disclosure, the first inorganic layer 171-1 may be formed after forming the first light-emitting element ED1, the second inorganic layer 171-2 may be formed after forming the second light-emitting element ED2, and the third inorganic layer 171-3 may be formed after forming the third light-emitting element ED3. That is to say, the first inorganic layer 171-1 may be formed prior to the second light-emitting element ED2 and the third light-emitting element ED3, and the second inorganic layer 171-2 may be formed prior to the third light-emitting element ED3.

In other words, the first inorganic layer 171-1 may be formed such that the shape of the first inorganic layer 171-1 completely covers the second emission area EA2 and the third emission area EA3, and the first inorganic layer 171-1 may then be removed from the second emission area EA2 and the third emission area EA3 via a dry etching process. In some embodiments, after the first inorganic layer 171-1 is formed, the second inorganic layer 171-2 may be formed such that the shape of the second inorganic layer 171-2 completely covers the first emission area EA1 and the third emission area EA3, and the second inorganic layer 171-2 may then be removed from the first emission area EA1 and the third emission area EA3 via a dry etching process. In some embodiments, after the first inorganic layer 171-1 and the second inorganic layer 171-2 are formed, the third inorganic layer 171-3 may be formed such that the shape of the third inorganic layer 171-3 completely covers the first emission area EA1 and the third emission area EA3, and the third inorganic layer 171-3 may then be removed from the first emission area EA1 and the second emission area EA2 via a dry etching process.

The first inorganic layer 171-1 and the second inorganic layer 171-2 formed via different processes may be spaced apart from each other on the second bank layer 163 of the bank structure 160. In some embodiments, the underlying patterns ELP1, CEP1 and 159-1 covered by the first inorganic layer 171-1 and the underlying patterns ELP2, CEP2 and 159-2 covered by the second inorganic layer 171-2 may be spaced apart from each other on the bank structure 160. Therefore, a portion of the second bank layer 163 of the bank structure 160 between the first inorganic layer 171-1 and the second inorganic layer 171-2 spaced apart from each other may be exposed, and the exposed portion of the second bank layer 163 may be in direct contact with a second encapsulation layer 173 of the thin-film encapsulation layer 170. Although the relationship between the first inorganic layer 171-1 and the second inorganic layer 171-2 has been described for convenience of illustration, it is to be understood that the relationship between the third inorganic layer 171-3 and the second inorganic layer 171-2 may include aspects of the relationship between the first inorganic layer 171-1 and the second inorganic layer 171-2. For example, the third inorganic layer 171-3 and the second inorganic layer 171-2 may be spaced apart from each other, and an exposed portion of the second bank layer 163 between the third inorganic layer 171-3 and the second inorganic layer 171-2 may be in direct contact with the second encapsulation layer 173.

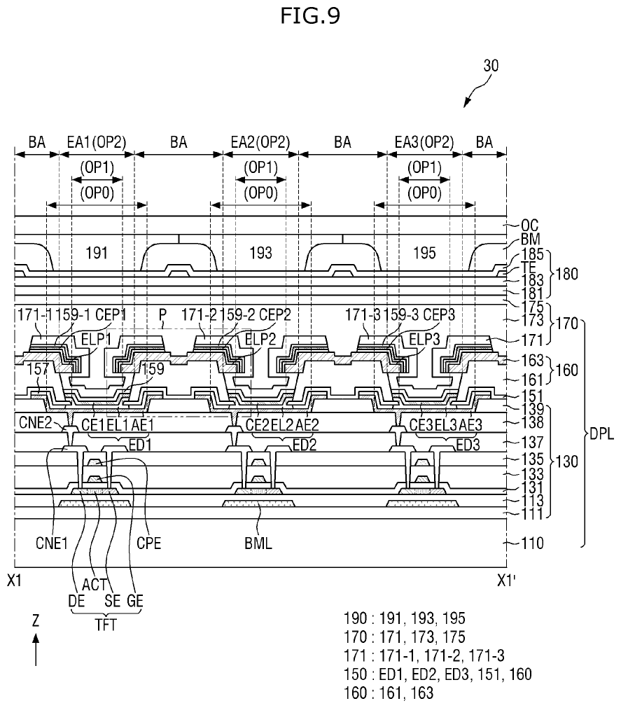

FIG. 9 is a cross-sectional view of a display device 30 in accordance with another example, taken along line X1-X1′ of FIG. 5.

The display device 30 of FIG. 9 is different from the display device 10 in that a thin-film transistor layer 130 further includes a subsidiary via layer 138 on a planarization layer 137, and a via layer 139 is disposed on the subsidiary via layer 138 in line with a non-emission area BA. For example, the via layer 139 may at least partially overlap the non-emission area BA. With reference to FIG. 9, unlike the display device 10 in which the via layer 139 includes a recess R or a protrusion P and the recess R and the protrusion P are fabricated via a single process, in the display device 30, the subsidiary via layer 138 is formed and then the via layer 139 is formed separately in line with the non-emission area BA.

In some embodiments, the subsidiary via layer 138 may overlap the emission areas EA1, EA2, and EA3 and the non-emission area BA, and may cover the second connection electrode CNE2 and the planarization layer 137. The subsidiary via layer 138 may include contact holes through which the pixel electrodes AE1, AE2 and AE3 of the light-emitting elements ED1, ED2 and ED3 pass. The subsidiary via layer 138 may be formed of an insulating material.

In some embodiments, the via layer 139 may be positioned on the subsidiary via layer 138 such that the via layer 139 overlaps the non-emission area BA. The via layer 139 may be fabricated via the same process as the subsidiary via layer 138 or may be fabricated via a different process. In some aspects, the via layer 139 may include the same material as the subsidiary via layer 138 or may include different materials from the subsidiary via layer 138.

In some embodiments, the via layer 139 of the display device 30 may form an opening OP0. The opening OP0 formed by the via layer 139 may overlap a first opening OP1 formed by the inorganic pixel-defining layer 151 and a second opening OP2 formed by the first bank layer 161. For example, the width of the opening OP0 formed by the via layer 139 may be greater than the width of the first opening OP1 formed by the inorganic pixel-defining layer 151 and the width of the second opening OP2 formed by the first bank layer 161. That is to say, for example, the first opening OP1 formed by the inorganic pixel-defining layer 151 and the second opening OP2 formed by the first bank layer 161 may be located within the opening OP0 formed by the via layer 139.

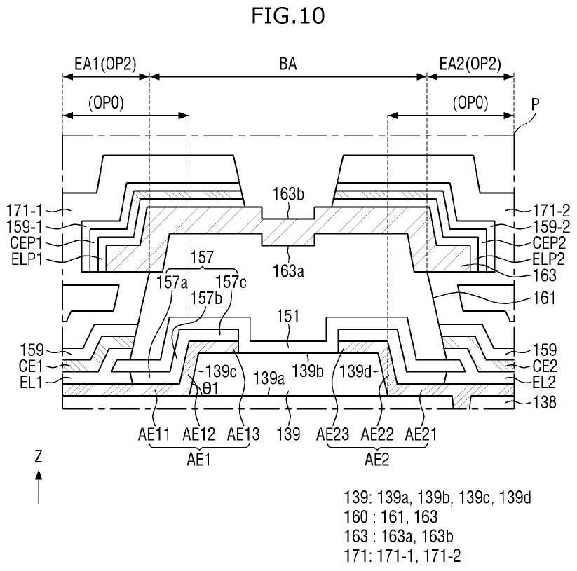

FIG. 10 is an enlarged cross-sectional view of area P of FIG. 9.

Referring to FIG. 10, the via layer 139 may include a first surface 139a in contact with the subsidiary via layer 138, and a second surface 139b opposite to (opposed to) the first surface 139a. The first surface 139a and the second surface 139b of the via layer 139 may be parallel to each other. The width of the first surface 139a of the via layer 139 may be greater than the width of the second surface 139b. In some aspects, the via layer 139 may include a first inclined surface 139c and a second inclined surface 139d connecting the first surface 139a of the via layer 139 with the second surface 139b of the via layer 139. For example, an inclination angle θ1 formed between the first surface 139a of the via layer 139 and a first inclined surface 139c of the via layer 139 may be an acute angle. Although not shown in the drawings, the inclination angle formed between the first surface 139a of the via layer 139 and the second inclined surface 139d of the via layer 139 may also be an acute angle. In some examples, the inclination angle formed between the first surface 139a and the second inclined surface 139d may be equal to inclination angle θ1.

The first pixel electrode AE1 located in the first emission area EA1 and the second pixel electrode AE2 located in the second emission area EA2 may be spaced apart from each other by the via layer 139. Expressed another way, the via layer 139 may be between the first pixel electrode AE1 and the second pixel electrode AE2.

In some embodiments, the first pixel electrode AE1 may include a first portion AE11 in contact with the subsidiary via layer 138, a second portion AE12 overlapping the non-emission area BA and in contact with the first inclined surface 139c of the via layer 139, and a third portion AE13 in contact with the second surface 139b of the via layer 139. In some embodiments, the second pixel electrode AE2 may include a first portion AE21 in contact with the subsidiary via layer 138, a second portion AE22 overlapping the non-emission area BA and in contact with the second inclined surface 139d of the via layer 139, and a third portion AE23 in contact with the second surface 139b of the via layer 139. As illustrated in the example of FIG. 10, the first pixel electrode AE1 and the second pixel electrode AE2 may be included in the non-emission area BA.

In some embodiments, the first portion AE11 and the second portion AE12 of the first pixel electrode AE1 may extend in directions away from each other, and the second portion AE12 and the third portion AE13 of the first pixel electrode AE1 may extend in directions away from each other. In some embodiments, the first portion AE21 and the second portion AE22 of the second pixel electrode AE2 may extend in directions away from each other, and the second portion AE22 and the third portion AE23 of the second pixel electrode AE2 may extend in directions away from each other. As shown in FIG. 10, the third portion AE13 of the first pixel electrode AE1 and the third portion AE23 of the second pixel electrode AE2 may be spaced apart from each other on the second surface 139b of the via layer 139.

In some embodiments, the first pixel electrode AE1 may include a step along the first inclined surface 139c of the first via layer 139. As described herein, the step included in the first pixel electrode AE1 may be formed such that the step does not overlap the tip TIP of the second bank layer 163. Although the first pixel electrode AE1 has been described for convenience of illustration, the second pixel electrode AE2 and third pixel electrode AE3 may include aspects of the first pixel electrode AE1 as described herein. For example, the pixel electrodes AE1, AE2, and AE3 of the display device 30 may all have the same structure. Additionally, or alternatively, respective structures of the pixel electrodes AE1, AE2, and AE3 may differ in-part.

The inorganic pixel-defining layer 151 may cover the first pixel electrode AE1 and the second pixel electrode AE2 in line with the non-emission area BA. For example, the inorganic pixel-defining layer 151 may cover along the first to third portions AE11, AE12, and AE13 of the first pixel electrode AE1 and the first to third portions AE21, AE22, and AE23 of the second pixel electrode AE2. It should be noted that the inorganic pixel-defining layer 151 may be in contact with the second surface 139b of the via layer 139 between the first pixel electrode AE1 and the second pixel electrode AE2 spaced apart from each other.

In some embodiments, the inorganic pixel-defining layer 151 may include a step along the first inclined surface 139c of the first via layer 139. In some embodiments, in some aspects, the inorganic pixel-defining layer 151 may include a step along the third portion AE13 of the first pixel electrode AE1. As described herein, the step included in the inorganic pixel-defining layer 151 may be formed such that the step does not overlap with the tip TIP of the second bank layer 163.

The residual pattern layer 157 may be disposed between the inorganic pixel-defining layer 151 and the pixel electrodes AE1, AE2 and AE3. As described herein, in the display device 30, a temporary protective layer may be disposed between the inorganic pixel-defining layer 151 and the pixel electrodes AE1, AE2 and AE3 and then partially removed during the fabrication process. The portion of the temporary protective layer that is not removed may remain in the display device 10 in the form of a residual pattern layer 157. Accordingly, the residual pattern layers 157 disposed in the emission areas EA1, EA2, and EA3, respectively, may be located in contact with the emissive layers EL1, EL2 and EL3 between the inorganic pixel-defining layer 151 and the pixel electrodes AE1, AE2 and AE3.

In some embodiments, the residual pattern layer 157 may cover along the pixel electrodes AE1, AE2 and AE3. Referring to FIG. 10, the residual pattern layer 157 may include a first portion 157a overlapping the first portion AE11 of the first pixel electrode AE1, a second portion 157b overlapping the second portion AE12 of the first pixel electrode AE1, and a third portion 157c overlapping the third portion AE13 of the first pixel electrode AE1.

In some embodiments, the residual pattern layer 157 disposed on the first pixel electrode AE1 and the residual pattern layer 157 disposed on the second pixel electrode AE2 may be spaced apart from each other on the second surface 139b of the via layer 139.

In some embodiments, the residual pattern layer 157 may include a step along the first inclined surface 139c of the first via layer 139. As described herein, the step included in the residual pattern layer 157 may be formed such that the step does not overlap with the tip TIP of the second bank layer 163.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area;
a via layer disposed on the substrate and comprising a recess toward the substrate;
a pixel-defining layer overlapping the non-emission area and disposed on the via layer;
a first bank layer disposed on the pixel-defining layer and defining a first opening;
a second bank layer disposed on the first bank layer and comprising a tip protruding toward the first opening from a side surface of the first bank layer;
a first pixel electrode overlapping the recess of the via layer and disposed on the substrate;
a first emissive layer disposed on the first pixel electrode in the first opening; and
a first common electrode disposed on the first emissive layer in the first opening and in contact with the first bank layer,
wherein the side surface of the first bank layer and the tip of the second bank layer overlap the recess of the via layer.

2. The display device of claim 1, wherein:
a first portion of the via layer has a first thickness and overlaps the recess;
a second portion of the via layer has a second thickness and does not overlap the recess; and
the first thickness is different from the second thickness.

3. The display device of claim 2, wherein the first thickness is smaller than the second thickness.

4. The display device of claim 3, wherein the first opening overlaps the recess of the via layer.

5. The display device of claim 4, wherein a width of the first opening in a direction parallel to the substrate is smaller than a width of the recess of the via layer.

6. The display device of claim 1, wherein the via layer further comprises an inclined surface overlapping the non-emission area and not overlapping the recess.

7. The display device of claim 6, wherein the first pixel electrode is in contact with the inclined surface.

8. The display device of claim 1, wherein the pixel-defining layer is spaced apart from the first pixel electrode in a direction perpendicular to the substrate in the recess of the via layer.

9. The display device of claim 8, further comprising:
a pattern layer disposed in a region where the first pixel electrode and the pixel-defining layer are spaced apart from each other,
wherein the pattern layer overlaps the recess of the via layer and is in contact with the first emissive layer.

10. The display device of claim 1, further comprising:
a first organic pattern disposed on the second bank layer, wherein the first organic pattern comprises a same material as the first emissive layer and is spaced apart from the first emissive layer; and
a first electrode pattern disposed on the first organic pattern, wherein the first electrode pattern comprises a same material as the first common electrode and is spaced apart from the first common electrode,
wherein the first organic pattern and the first electrode pattern overlap the recess of the via layer.

11. The display device of claim 10, further comprising:
a second pixel electrode spaced apart from the first pixel electrode, wherein the via layer is interposed between the second pixel electrode and the first pixel electrode;
a second emissive layer disposed on the second pixel electrode;
a second common electrode on the second emissive layer; and
a second electrode pattern disposed on the second bank layer, wherein the second electrode pattern comprises a same material as the second common electrode and is spaced apart from the second common electrode.

12. The display device of claim 11, further comprising:
a first inorganic layer covering the first common electrode and the first electrode pattern; and
a second inorganic layer covering the second common electrode and the second electrode pattern,
wherein the first inorganic layer and the second inorganic layer are spaced apart from each other.

13. The display device of claim 1, further comprising:
a subsidiary via layer disposed between the substrate and the via layer,
wherein a surface of the subsidiary via layer overlaps the recess of the via layer and is exposed by the recess, and wherein the exposed surface of the subsidiary via layer is in contact with the first pixel electrode.

14. The display device of claim 13, wherein the via layer comprises:
a first surface facing the subsidiary via layer;
a second surface opposed to the first surface; and
an inclined surface connecting the first surface with the second surface.

15. The display device of claim 14, wherein a width of the first surface is greater than a width of the second surface, and wherein an angle formed by the first surface and the inclined surface is an acute angle.

16. The display device of claim 15, wherein the via layer and the subsidiary via layer comprise a same material.

17. The display device of claim 15, wherein the via layer and the subsidiary via layer comprise different materials.

18. A display device comprising:
a substrate comprising an emission area and a non-emission area;
a via layer disposed on the substrate and comprising a recess toward the substrate;
a pixel-defining layer overlapping the non-emission area, disposed on the via layer and defining a first opening;
a first bank layer overlapping the non-emission area and disposed on the pixel-defining layer;
a second bank layer disposed on the first bank layer and comprising a tip protruding toward the first opening from a side surface of the first bank layer;
a first pixel electrode disposed on the via layer in the recess of the via layer;
a first emissive layer disposed on the first pixel electrode in the first opening; and
a first common electrode disposed on the first emissive layer in the first opening and in contact with the first bank layer,
wherein the first opening overlaps the recess of the via layer.

19. The display device of claim 18, wherein a width of the first opening is smaller than a width of the recess of the via layer.

20. The display device of claim 19, wherein a side surface of the pixel-defining layer facing the first opening is located in the recess of the via layer, and the side surface of the pixel-defining layer overlaps the via layer in a direction parallel to the substrate.
